(19) United States
(12) Patent Application Publication
(10) Pub. No.: US 2024/0170434 A1
(43) Pub. Date: May 23, 2024

(54) BACK SIDE METALLIZATION THIN FILM STRUCTURE AND METHOD FOR FORMING THE SAME

(71) Applicant: AG MATERIALS TECHNOLOGY CO., LTD., Hsinchu City (TW)

(72) Inventor: Chien-Hsun CHUANG, Hsinchu City (TW)

(21) Appl. No.: 18/193,012

(22) Filed: Mar. 30, 2023

(30) Foreign Application Priority Data
Nov. 22, 2022 (TW) 111144526

(51) Int. Cl. H01L 23/00

(52) U.S. Cl. CPC H01L 24/29; H01L 24/27; H01L 2224/2745; H01L 2224/29082; H01L 2224/29124; H01L 2224/29139; H01L 2224/29144; H01L 2224/29147; H01L 2224/29155; H01L 2224/29164; H01L 2224/29166; H01L 2224/29171

(57) ABSTRACT

A back side metallization thin film structure is provided, which includes a wafer and a metallic nano-twinned thin film on the back side of the wafer. A plurality of integrated circuit devices are formed on the front side of the wafer. The metallic nano-twinned thin film includes silver, copper, gold, palladium, or nickel. The metallic nano-twinned thin film has a transition layer near the wafer and a twin layer away from the wafer. The twin layer accounts for at least 70% of the thickness of the metallic nano-twinned thin film and includes parallel-arranged twin boundaries. The parallel-arranged twin boundaries include more than 50% of (111) crystal orientation. The back side metallization thin film structure is formed by activating the wafer surface by ion beam bombardment, followed by an evaporation deposition process performed on the activated wafer surface with simultaneous ion beam bombardment.

### CROSS REFERENCE TO RELATED APPLICATIONS

This application claims priority of Taiwan Patent Application No. 111144526, filed on Nov. 22, 2022, the entirety of which is incorporated by reference herein.

### BACKGROUND

### Technical Field

The present disclosure relates to a metallic thin film structure and a method for forming the same, and, in particular, to the back side metallization thin film structure and a method for forming the same.

### Description of the Related Art

One of the most important components of an electronic device that can affect its power conversion efficiency is the power module. Electronic devices have to meet extremely high requirements on the reliability of the power module, so the packaging technology and the material selection of the power module are quite difficult. In general, power module packaging includes conducting the back side metallization of a power integrated circuit chip and then fixing the chip on a ceramic substrate (i.e., die bonding). The die bonding process in the prior art uses solder alloy soldering, solid liquid interdiffusion bonding (SLID), or silver sintering.

The back side metallization in the prior art mainly adopts titanium (Ti)/nickel (Ni)/silver (Ag) thin film structure, wherein the Ti film is used mainly as an adhesive layer between a silicon wafer and the back side metallization thin film above the silicon wafer, the Ni thin film is used mainly as a diffusion barrier layer between a bonding filler metal and the Ti adhesive layer for die-bonding in the prior art using soldering, solid liquid interdiffusion bonding, and silver sintering, and the uppermost Ag thin film is used as the reaction layer of the bonding filler metal of soldering and silver sintering for subsequent die bonding. The bonding temperature of the thin film structure must be higher than 250° C. However, since Ni and Ag do not react at all on the phase equilibrium diagram, Ni/Ag interfacial separation can easily occur, causing damage to the back side metallization.

Therefore, the industry has begun to try to use other thin film structures for back side metallization, such as metallic nano-twinned thin film structures.

Aiming at metallic nano-twinned thin films, U.S. Patent Publication No. US20150275350 A1 discloses a structure of silver or silver alloy nano-twinned thin film sputtered directly on a silicon substrate. The silver or silver alloy nano-twinned thin film has better tensile strength and conductivity than ordinary grains or nano equiaxial grains. However, the silver or silver alloy nano-twinned density is less than 30%.

Taiwan Patent No. 1703226 discloses a structure of silver nano-twinned thin film sputtered on surface of a silicon chip, and its nano-twinned density can reach 75%. However, the sputtering method is extremely costly and the production rate is low. It is known that evaporation of thin films has the advantages of low cost and high production efficiency. Although Taiwan Patent No. 1703226 also discloses a structure of silver nano-twinned thin film evaporated directly on the surface of a silicon chip, its nano-twinned density is only 50%, especially on a large wafer, it is difficult to produce a nano-twinned structure uniformly distributed over the entire area and with a density of 50%. Regardless of whether sputtering or direct evaporation method is used, Taiwan Patent No. 1703226 fails to disclose the formation of high-density nano-twinned thin film structures of copper, gold, palladium or nickel.

Taiwan Patent No. 1419985 discloses the electroplating of silver, copper, gold or nickel thin film on a silicon oxide substrate. The metal thin film formed by the electroplating is then bombarded with ions to form mechanical twins. However, the distance between twin boundaries is between 8.3 nm and 45.6 nm. The distribution of crystal orientation is disordered, and a large number of parallel-arranged nano twins of (111) preferred orientation cannot be formed. The nano-twinned density is also less than 50%.

Taiwan Patent No. 1432613 discloses a method for electroplating a copper nano-twinned thin film. Taiwan Patent No. 1521104 discloses a method for electroplating a copper seed layer and then electroplating nickel nano-twinned thin film. Taiwan Patent No. 1507548 discloses a method for electroplating a gold nano-twinned thin film. These conventional techniques can form a large number of parallel-arranged nano-twinned thin films on a substrate. However, they all use a high-speed rotary electroplating method with a speed of 50 rpm or even 1,500 rpm. It is difficult to control the process and film quality, and on a large wafer, it is especially difficult to produce a nano-twinned structure uniformly distributed over the entire area and with a density of 50%. In addition, there are also environmental concerns surrounding the waste produced by the electroplating process.

In summary, there are still many areas of back side metallization with nano-twinned thin films that need to be improved.

### SUMMARY

An embodiment of the present disclosure provides the back side metallization thin film structure, including a wafer and a metallic nano-twinned thin film. There is a plurality of integrated circuit devices formed on the front side of the wafer. The metallic nano-twinned thin film is on the back side of the wafer. The metallic nano-twinned thin film includes silver, copper, gold, palladium or nickel. The metallic nano-twinned thin film includes a transition layer near the wafer and a twin layer away from the wafer. The twin layer accounts for at least 70% of the thickness of the metallic nano-twinned thin film and includes parallel-arranged twin boundaries. The average distance between the parallel-arranged twin boundaries is 1 nm to 100 nm. The parallel-arranged twin boundaries include no less than 50% of (111) crystal orientation.

An embodiment of the present disclosure provides a method of forming the back side metallization thin film structure. The method includes providing a wafer, wherein a plurality of integrated circuit devices are disposed on the front side of the wafer. The method includes activating the back side of the wafer using ion beam bombardment. The method includes forming a metallic nano-twinned thin film on the activated back side of the wafer by ion-beam bombardment-assisted evaporation. The metallic nano-twinned thin film includes silver, copper, gold, palladium or nickel. The metallic nano-twinned thin film includes a transition layer near the wafer and a twin layer away from the wafer. The twin layer accounts for at least 70% of the thickness of the metallic nano-twinned thin film and includes parallel-arranged twin boundaries. The average distance between the parallel-arranged twin boundaries is 1 nm to 100 nm. The parallel-arranged twin boundaries include no less than 50% of (111) crystal orientation.

### BRIEF DESCRIPTION OF THE DRAWINGS

Aspects of this disclosure are best understood from the following detailed description when read with the accompanying figures. It should be noted that, in accordance with common practice in the industry, various features are not drawn to scale. In fact, the dimensions of the various features may be arbitrarily increased or reduced for clarity of discussion.

FIG. 1 shows a focused ion beam (FIB) image of the Ti/Ni/Ag back side metallization layer structure in the prior art.

FIG. 2 shows the schematic diagram of applying ion beam bombardment to activate the surface of a wafer before evaporation and forming a metallic nano-twinned thin film by ion-beam bombardment-assisted evaporation, according to the some embodiments of the present disclosure.

FIGS. 3A-3C show the schematic diagrams of the back side metallization thin film structure in various process stages respectively according to some embodiments of the present disclosure.

FIGS. 4A-4C show the schematic diagrams of the back side metallization thin film structure in various process stages respectively according to other embodiments of the present disclosure.

FIG. 5 shows a focused ion beam (FIB) image of a cross-section of a high-density silver (Ag) nano-twinned thin film formed on an 8-inch silicon wafer present disclosure according to some embodiments of the present disclosure.

### DETAILED DESCRIPTION OF THE INVENTION

The following disclosure provides many different embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Some variations of embodiments are described below. In different figures and illustrated embodiments, similar element symbols are used to indicate similar elements. It is appreciated that additional operations can be provided before, during, and/or after the stages described in these embodiments. Some of the stages that are described can be replaced or eliminated for different embodiments.

Furthermore, spatially relative terms, such as “beneath,” “below,” “lower,” “overlapped,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Furthermore, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The term “substantially” in the description, such as in “substantially peeling” will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%.

The difference between the present disclosure and the back side metallization method in the prior art will be described below.

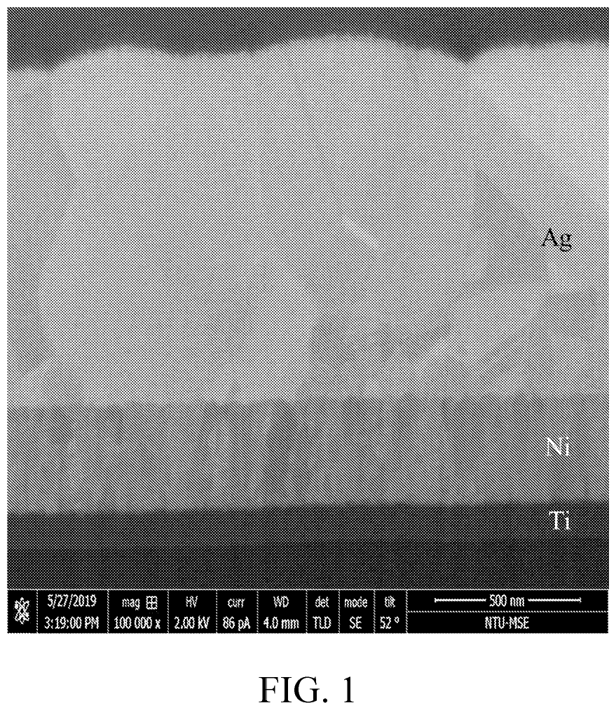

First, refer to FIG. 1, which is a focused ion beam (FIB) image showing Ti/Ni/Ag back side metallization layer structure in the prior art. The uppermost Ag thin film has an equiaxial coarse-grain structure with a grain size of 100 nm to 500 nm. Since the Ag film is relatively thick and needs to be bonded at high temperature, it is likely to cause damage to the device due to high temperature. In addition, since Ni and Ag do not react at all on the phase equilibrium diagram, Ni/Ag interface separation can easily occur, causing damage to the back side metallization.

In contrast, a novel back side metallization thin film structure is provided in the present disclosure, the metallic nano-twinned thin film of the structure may be silver, copper, gold, palladium or nickel. The thickness of the metallic nano-twinned thin film is between 0.01 μm and 10 μm. The metallic nano-twinned thin film includes a transition layer, and a twin layer on the transition layer, wherein the twin layer accounts for at least 70% of the thickness of the metallic nano-twinned thin film. The twin layer has parallel-arranged twin boundaries, the average distance between the parallel-arranged twin boundaries is between 1 nm and 100 nm, and the parallel-arranged twin boundaries includes more than 50% of (111) crystal orientation.

Since the atomic diffusion coefficient of the (111) crystal orientation is 3 to 4 orders of magnitude higher than that of (100) or (110) crystal orientations, the inventors of the present disclosure discovered that through a thin film with no less than 50% of (111) crystal orientations in the twin layer, the chip can be bonded directly to the substrate at a low temperature below 250° C. Without using soldering or silver sintering paste, the Ni diffusion barrier layer of the back side metallization layer structure in the prior art is not required, so there is no Ni/Ag interface separation and damage problems that often occur in back side metallization layer structure. Besides, in addition to the characteristics of the metal itself, the characteristics of the twin structure, such as better oxidation resistance, corrosion resistance, electrical conductivity, thermal conductivity, high temperature stability, etc., make the present disclosure have better application advantages.

The method of forming the invention of present disclosure is illustrated below referring to the drawings

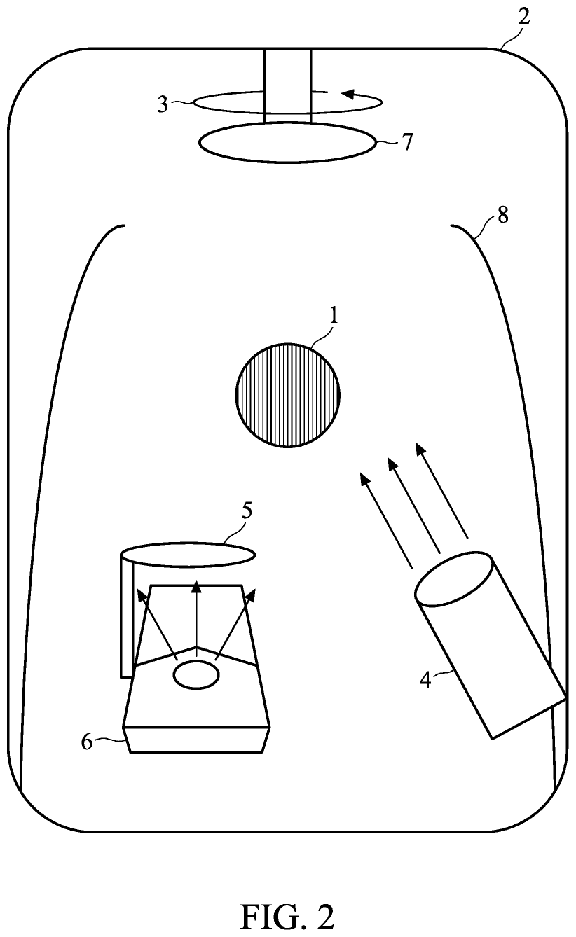

Referring to FIG. 2, which shows the schematic diagram of the method of applying ion beam bombardment to activate the surface of the wafer before evaporation, and forming a metallic nano-twinned thin film by ion-beam bombardment-assisted evaporation, according to the present disclosure. The method of forming the back side metallic thin film structure mainly includes: evaporation chamber pressure adjusting, activating, and thin film forming.

The step of evaporation chamber pressure adjusting includes: after placing the sample 7 on the holder 3, pre-evacuating the chamber 2 to a vacuum degree less than 6×10⁻⁶ Torr (for example, 1×10⁻⁸ Torr to 5×10⁻⁶ Torr, 5×10⁻⁸ Torr to 1×10⁻⁶ Torr, or 1×10⁻⁷ Torr to 5×10−7 Torr); introducing 99.9%-99.999% high-purity argon into the chamber 2, wherein the flow rate is set to 1 sccm to 10 sccm (such as 3 sccm to 7 sccm, 4.5 sccm to 5.5 sccm) by the mass flow controller; and until the flow is stable, controlling the pressure of the chamber 2 to the required pressure of 1×10⁻⁵ to 1×10⁻³ Torr (for example, 3×10⁻⁵ Torr to 7×10⁻⁴ Torr, 6×10⁻⁵ Torr to 4×10⁻⁴ Torr, and 9×10⁻⁵ Torr to 1.5×10−4 Torr).

The step of activating includes: setting the rotating speed of the Holder 3 to 5 rpm to 20 rpm (such as 7 rpm to 18 rpm, 9 rpm to 16 rpm, and 11 rpm to 14 rpm); opening the ion source 4; setting the voltage and electric current of the ion source 4; and conducting the surface activation on the sample 7 on the Holder 3, wherein the activation of the sample 7 lasts for 10-30 minutes.

Then follows the film forming step, which includes: opening the electron beam and adjusting the position of the electron beam by the control handle; increasing the power of the electron beam; and after evaporating the evaporation material in the crucible 6 by the electron beam, depositing the back side metallization layer on sample 7 by evaporation with shutter 5 opened. The ion source 4 can be temporarily turned off after the activation of the sample 7 is completed, and then turned on again after the film is formed to a certain thickness (for example, 1%-10% of the predetermined film thickness), or it can be left open until the evaporation of the thin film is completed. During the evaporation process, the quartz detector 8 is used to detect the film thickness on the sample 7, and the evaporation and ion beam bombardment can be stopped when the film thickness reaches a predetermined value.

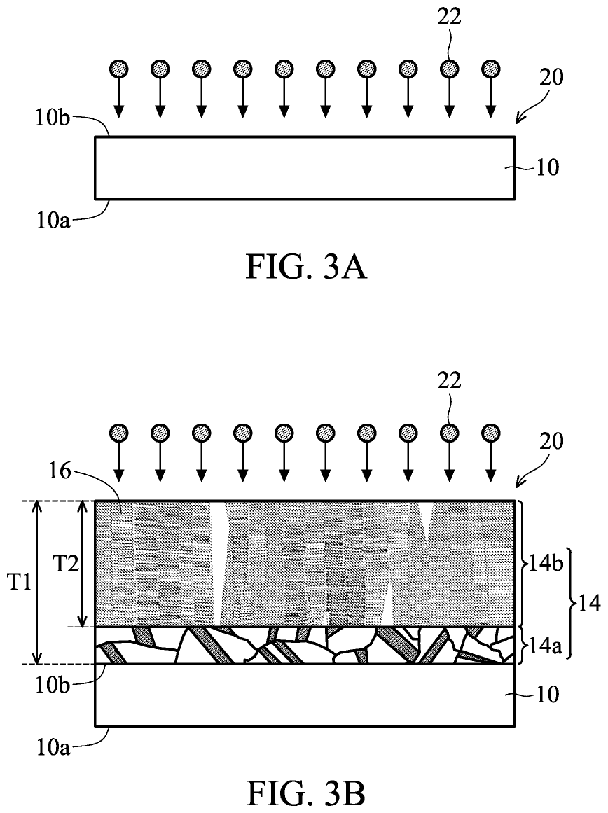

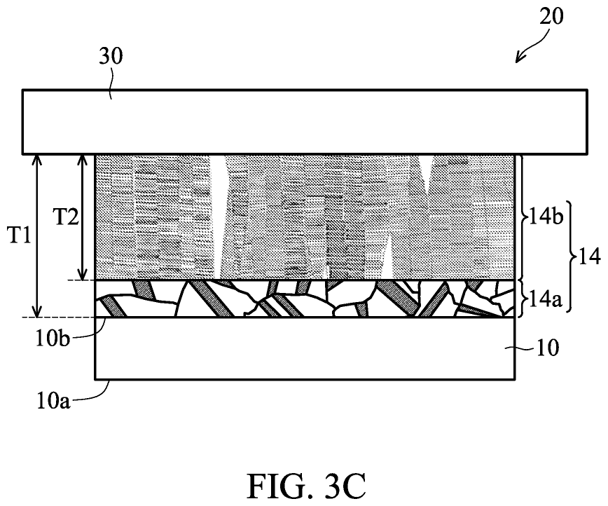

FIGS. 3A-3C illustrate a method of forming the back side metallization thin film structure 20 according to some embodiments. As shown in FIG. 3A, a wafer 10 is provided. In some embodiments, the wafer 10 includes a single crystal of silicon, silicon carbide, gallium arsenide, sapphire, or a combination thereof. In some embodiments, the wafer 10 is a 6-inch wafer, an 8-inch wafer, or a 12-inch wafer. The front side 10a of the wafer 10 has a plurality of integrated circuit devices, such as power devices, light-emitting devices, etc. The back side 10b opposite to the front side 10a of the wafer 10 is activated by ion beam bombardment 22 to facilitate the subsequent formation of a twin structure on the back side 10b. In some embodiments, the ion beam bombardment 22 of the activation process has a power of 20 W to 100 W (e.g., 25 W to 95 W, 35 W to 85 W, 45 W to 75 W, or 55 W to 65 W) and a duration of 10 minutes to 60 minutes (e.g., 15 minutes to 55 minutes, 20 minutes to 50 minutes, 25 minutes to 45 minutes, or 30 minutes to 40 minutes). In some embodiments, the ion beam bombardment 22 of the activation process may use an argon ion beam or an oxygen ion beam, and the voltage of the ion gun may be from −200V to −800V.

Next, as shown in FIG. 3B, the metallic nano-twinned thin film 14 is formed directly on the back side 10b of the activated wafer 10 by evaporation while applying bias voltage to the wafer 10 and conducting ion beam bombardment 22 on the evaporated thin film surface during the evaporation process. In some embodiments, the vacuum degree of the evaporation process may be, for example, 10⁻⁶ Torr to 10⁻² Torr (for example, 5×10⁻⁶ Torr to 5×10⁻² Torr, 1×10⁻⁵ Torr to 1×10⁻³ Torr, 5×10⁻⁵ Torr to 5×10⁻³ Torr, or 1×10−4 Torr to 5×10⁻⁵ Torr). The scanning frequency of the evaporation electron beam may be, for example, about 2 Hz to 10 Hz (such as 3 Hz-9 Hz, 4 Hz-8 Hz, 5 Hz-7 Hz, or 5.5 Hz-6 Hz), and the rotation speed of the evaporation holder 3 may be 1 rpm to 20 rpm (such as 3 rpm to 17 rpm, 6 rpm to 14 rpm, or 9 rpm to 11 rpm), the evaporation rate of the metallic nano-twinned thin film 14 may be, for example, 0.1 nm/s to 100 nm/s (such as 1 nm/s to 90 nm/s, 5 nm/s to 85 nm/s, 10 nm/s to 80 nm/s, 15 nm/s to 70 nm/s, 30 nm/s to 60 nm/s, or 40 nm/s to 50 nm/s). During evaporation, a bias voltage of −100V to −500V (such as −150V to −450V, −200V to −400V, or −250V to −350V) is applied to the wafer 10. It should be understood that, the above evaporation process parameters can be properly adjusted according to actual applications, and the present disclosure is not limited thereto. In some embodiments, the power of the ion beam bombardment 22 during the evaporation process is 20 W to 100 W, and the ion beam bombardment 22 lasts until the end of the evaporation. Ion beam bombardment 22 in the evaporation process may use argon ion beam or oxygen ion beam, the flow rate of the ion beam may be 1 sccm to 20 sccm (such as 3 sccm to 17 sccm, 6 sccm to 14 sccm, or 9 sccm to 11 sccm), the voltage of the ion gun may be 10V to 5 KV (such as 50V to 1 KV, 100V to 900V, 300V to 700V, or 400V to 600V), and the current of the ion gun may be 0.2 A to 20 A (such as 0.3 A to 18 A, 1 A to 15 A, 3 A to 12 A, 5 A to 10 A, or 6 A to 8 A). The parameters of the ion beam bombardment 22 in the activation process and the ion beam bombardment 22 in the evaporation process may be the same or different.

In some embodiments, the metallic nano-twinned thin film 14 includes a transition layer 14a close to the wafer 10, and a twin layer 14b away from the wafer 10, as shown in FIG. 3B. The metallic nano-twinned thin film 14 has a thickness of T1, wherein the twin layer 14b of the metallic nano-twinned thin film 14 has a thickness of T2, and the transition layer 14a of the metallic nano-twinned thin film 14 has a thickness that is substantially equal to the difference between T1 and T2. In some embodiments, the thickness T1 of the metallic nano-twinned thin film 14 is about 0.01 μm to 10 μm (such as 0.05 μm to 8 μm, 1.0 μm to 6 μm, 1.5 μm to 4 μm, or 2 μm to 3 μm). In some embodiments, the thickness T2 of the twin layer 14b of the metallic nano-twinned thin film 14 is about 0.007 μm to 9.8 μm (for example, 0.01 μm to 9 μm, 0.1 μm to 8.5 μm, 0.5 μm to 8 μm, 1 m to 7.5 μm, 1.5 μm to 7 μm, 2 μm to 6 μm, or 3 μm to 5 μm). In some embodiments, the twin layer 14b of the metallic nano-twinned thin film 14 has parallel-arranged high-density twin boundaries. The average distance between the parallel-arranged high-density twin boundaries is 1 nm to 100 nm (such as 10 nm to 90 nm, 15 nm to 80 nm, 20 nm to 70 nm, 25 nm to 60 nm, 30 nm to 50 nm, or 35 nm to 40 nm), and the parallel-arranged high-density twin boundaries include no less than 50% of (111) crystal orientations (such as 51% to 99%, 56% to 94%, 61% to 89%, 66% to 84%, or 71% to 79%). In some embodiments, the thickness T2 of the twin layer 14b is greater than 70% (such as 71%-99%, 74%-96%, 77%-93%, 80%-90%, 83%-87%) of the thickness T1 of the metallic nano-twinned thin film 14, that is, the thickness of the transition layer 14a with disordered grains is less than 30% (such as 1%-29%, 4%-26%, 7%-23%, 10%-20%, 13%-17%) of the thickness T1 of the metallic nano-twinned thin film 14. According to some embodiments, as shown in FIG. 3B, the twin layer 14b of the metallic nano-twinned thin film 14 includes a plurality of nano-twinned pillars 16. In some embodiments, the nano-twinned pillar 16 has a diameter of 0.01 m to 10 μm (e.g., 0.1 μm to 8 μm, 0.5 μm to 6 μm, 0.7 μm to 5 μm, 1 μm to 4 μm, or 2 μm to 3 μm).

In some embodiments, the metallic nano-twinned thin film 14 substantially covers the entirety of the back side 10b of the wafer 10. In some embodiments, the metallic nano-twinned thin film 14 covers more than 90%, such as 91%-99%, 92%-98%, 93%-97%, or 94%-96% of the surface area of the back side 10b of the wafer 10.

In the present disclosure, the surface of the wafer is activated by conducting the ion beams bombardment before forming the thin film, so that the density of dangling bonds on the surface of the wafer increases. Since the dangling bonds are a high-energy reconstruction structure, it is beneficial for the metallic nano thin film subsequent formed on the wafer to obtain additional energy, thereby a twin structure is formed. In addition, ion beams bombardment is also conducted during the evaporation process. Since the metallic film undergoes solidification reaction and cooling volume shrinkage phenomenon during the evaporation process, the shrinkage rate of the metal is about 15 ppm/K to 20 ppm/K, which is higher than that of silicon chips (3 ppm/K), after being solidified and then cooled to room temperature, the metallic thin film will form tensile stress. The ion-beam bombardment can apply compressive stress to the metallic thin film and relax the tensile stress of the metallic thin film (i.e. stress relaxation). The stress relaxation can trigger the formation of nano twins, and successfully make the evaporated silver film have high-density nano-twins. The use of the ion-beam bombardment-assisted evaporation method also proves that high-density nano-twinned thin film structures of copper, gold, palladium and nickel can be obtained.

According to some embodiments, as shown in FIG. 3C, the back side metallization thin film structure 20 further includes a substrate 30, and the substrate 30 is bonded to the back side 10b of the wafer 10 through the metallic nano-twinned thin film 14. In some embodiments, the substrate 30 is a ceramic substrate, such as an alumina substrate, an aluminum nitride substrate, a silicon carbide substrate, a beryllium oxide substrate, or the like. In some embodiments, after the substrate 30 and the back side metallization thin film structure 20 are stacked together, they are heated to be bonded, at a vacuum degree about 1×10⁻⁶ Torr to 1×10⁻⁴ Torr (for example, 3×10⁻⁶ Torr to 7×10⁻⁵ Torr, 5×10⁻⁶ Torr to δ×Torr⁻⁵, 7×10⁻⁶ Torr to 3×10⁻⁵ Torr, or 9×10⁻⁶ Torr to 1×10−5 Torr), under a pressure about 10 MPa to 30 MPa (such as 13 Mpa to 27 MP, 15 Mpa to 25 MP, or 18 Mpa to 22 MP), and at a temperature below 250° C. (such as 100° C.-230° C., 130° C.-210° C., 160° C.-190° C. or 170° C.-180° C.) for 10-30 minutes (such as 13-27 minutes, 15-25 minutes, or 18-22 minutes).

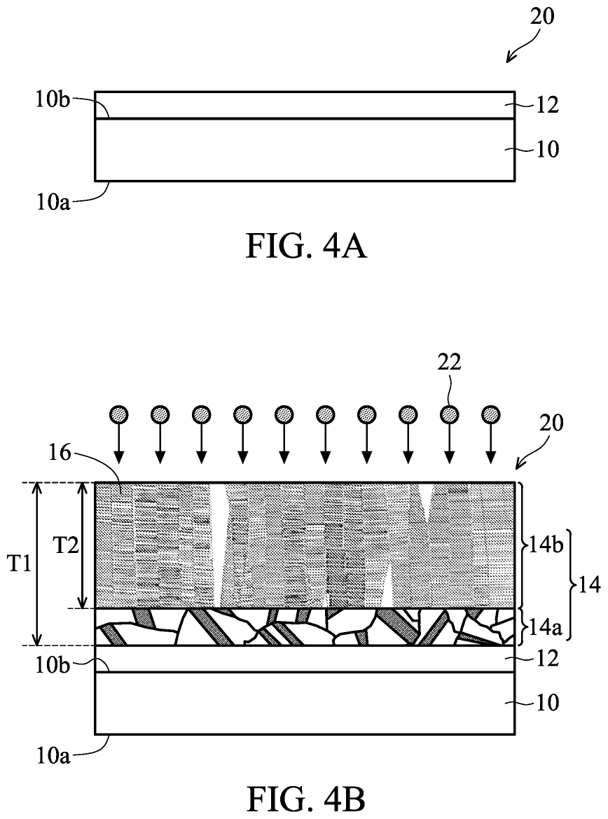

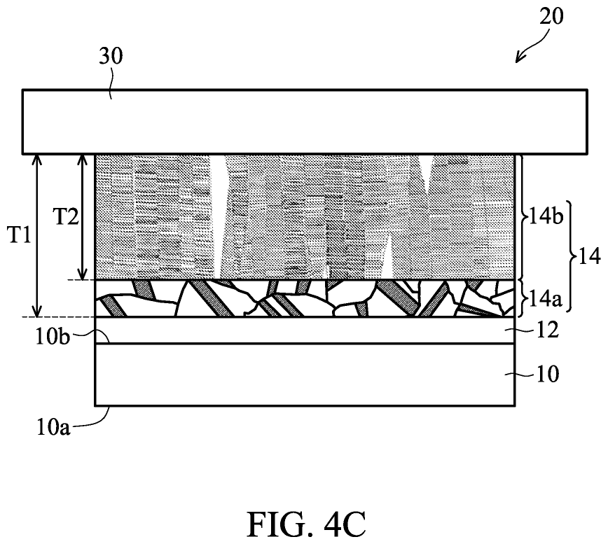

FIGS. 4A-4C illustrate another method for forming the back side metallization thin film structure 20 according to other embodiments. The embodiments of FIG. 4A-4C further includes an adhesive layer 12 between the wafer 10 and the metallic nano-twinned thin film 14 comparing to the embodiments of FIGS. 3A-3B.

Referring to FIG. 4A, in some embodiments, the material of the substrate 10 may refer to the embodiment shown in FIG. 3A, which will not be repeated here. The process of FIG. 4A follows that of FIG. 3A, that is, after activating the back side 10b of the wafer 10, an adhesive layer 12 is formed on the back side 10b of the wafer 10. In some embodiments, the adhesive layer 12 may include titanium, chromium, aluminum, or a combination thereof. In some embodiments, the adhesive layer 12 has a thickness of 0.01 m to 1 μm (e.g., 0.05 μm to 0.8 μm, 0.1 μm to 0.6 μm, 0.2 μm to 0.5 μm, 0.3 μm to 0.4 m). In some embodiments, the thickness of the titanium-containing adhesive layer 12 may be 0.01 μm to 0.1 μm, such as 0.1 μm to 0.05 μm. In some embodiments, the thickness of the chromium-containing adhesive layer 12 may be 0.05 μm to 1 μm, for example, 0.1 μm to 0.5 μm. In some embodiments, the thickness of the aluminum-containing adhesive layer 12 may be 0.1 μm to 1 μm, such as 0.1 μm to 0.5 μm. It should be understood that, the thickness of the adhesive layer 12 can be properly adjusted according to practical applications, and the present disclosure is not limited thereto. The adhesive layer 12 provides better bonding force between the wafer and the metallic nano-twinned thin film. At the same time, it has the effect of lattice buffering, so the ratio of the thickness of the twin layer 14b in the metallic nano-twinned thin film 14 can be improved, for example, by more than 5% (such as 6%-50%, 10%-46%, 14%-42%, 18%-38%, 22%-34%, 26%-30%).

According to some embodiments of the present disclosure, the adhesive layer 12 may be formed on the back surface 10b of the wafer 10 by sputtering or evaporation.

In some embodiments, the sputtering of the adhesive layer 12 adopts single-gun sputtering or multi-gun co-sputtering. In the sputtering process, the power source may use, for example, DC, DC plus, RF, or high-power impulse magnetron sputtering (HIPIMS). The sputtering power of the adhesive-lattice-buffer layer 12 may be, for example, about 100 W to about 500 W. The temperature of the sputtering process is room temperature, but the temperature will rise by about 50° C. to about 200° C. during the sputtering process. The background pressure of the sputtering process is about 1×10⁻⁵ Torr to 5×10⁻⁵ Torr. The working pressure may be, for example, about 1×10⁻³ Torr to about 1×10⁻² Torr. The flow rate of argon is about 10 sccm to about 20 sccm. The rotation speed of the holder may be, for example, about 5 rpm to about 20 rpm. The bias voltage applied to the wafer during the sputtering process is about −100V to about −200V. The deposition rate of the adhesive layer 12 may be, for example, about 0.5 nm/s to about 3 nm/s. It should be understood that, the parameters of the sputtering process described above may be appropriately adjusted according to practical applications, and the present disclosure is not limited thereto.

In some embodiments, the background pressure of the evaporation process of the adhesive layer 12 is about 1×10⁻⁵ Torr to 5×10⁻⁵ Torr. The working pressure may be, for example, about 1×10⁻⁴ Torr to about 5×10⁻⁴ Torr. The flow rate of argon is about 2 sccm to about 10 sccm. The rotation speed of the holder may be, for example, about 5 rpm to about 20 rpm. The deposition rate of the adhesive layer 12 may be, for example, about 1 nm/s to about 5.0 nm/s. It should be understood that, the parameters of the evaporation process described above may be appropriately adjusted according to practical applications, and the present disclosure is not limited thereto.

Then referring to FIG. 4B, a bias voltage is applied to the wafer 10 while evaporating on the adhesive layer 12, and ion beam bombardment 22 is conducted to assist the formation of the metallic nano-twinned thin film 14, and the metallic nano-twinned thin film 14 is formed on the surface of the adhesive layer 12 away from the wafer 10. The structure and formation method of the metallic nano-twinned thin film 14 can refer to the embodiments shown in FIG. 3B so will not be repeated here. In some embodiments, as shown in FIG. 4C, the substrate 30 is bonded to the back side 10b of the wafer 10 through the metallic nano-twinned thin film 14, wherein the material of the substrate 30 and the step of bonding in FIG. 4C can refer to the embodiments shown in FIG. 3C, so will not be repeated here.

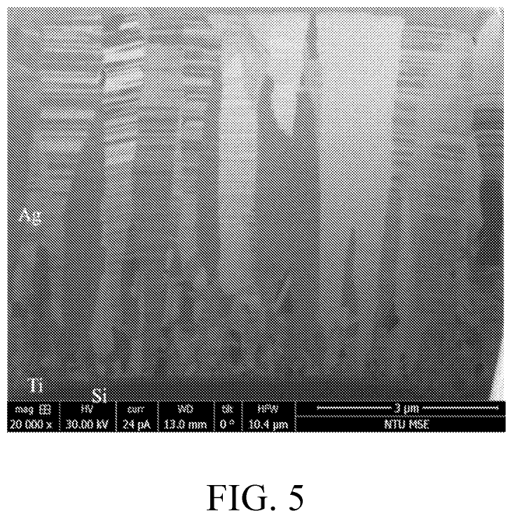

FIG. 5 shows a partial FIB image of a metallic nano-twinned thin film formed on an 8-inch silicon wafer by the method of the present disclosure according to an embodiment. In this embodiment, the surface of the wafer is first activated by conducting an ion-beam bombardment with a power of 50 W and a duration of 30 minutes, and then the evaporation deposition is conducted on the activated surface of the wafer. During the evaporation process, a voltage bias of 240V and a current of 5 A are applied to the wafer, the flow rate of argon gas of evaporation is 16.7 sccm, and an ion-beam bombardment with a power of 150 W is conducted to the surface of the deposited film to assist the formation of a high-density silver (Ag) nano-twinned thin film. As shown in the FIB image of FIG. 5, the twin layer of the silver nano-twinned thin film formed by the method of the present disclosure has parallel-arranged high-density twin boundaries, and the distance between the parallel-arranged high-density twin boundaries is 2 to 15 nm. The twin layer accounts for about 86% of the thickness of the silver nano-twinned thin film, that is, the thickness of the remaining transition layer with disordered grain only accounts for about 14% of the thickness of the silver nano-twinned thin film. In addition, according to Electron Back Scatter Diffraction (EBSD) image of the embodiment, it can be known that the parallel-arranged high-density twin boundaries include 92% of (111) crystal orientation.

In one embodiment, on an 8-inch silicon wafer after 30 minutes of ion beam bombardment at 300 W, a 4-micron silver (Ag) nano-twin film was formed by evaporating while applying a 240 V bias and ion-beam bombarding with a voltage of 240 V and a current of 5 A, wherein the thickness of the twin layer in the nano-twinned thin film is 3.3 m. From the Electron Back Scatter Diffraction (EBSD) image, it can be known that the twin layer of the silver nano-twinned thin film has 85% of (111) crystal orientation, and the proportion of CSL-E3 twin boundary is 38.5%.

In another embodiment, on an 8-inch silicon wafer after conducting 30 minutes of ion beam bombardment to the wafer at 300 W, a silver (Ag) nano-twinned thin film of 4 m was formed by evaporation. Since the evaporation was conducted without the assistance of the ion-beam bombardment, the thickness of the twin layer in the nano-twinned thin film is only 2.5 μm. It can be seen from the EBSD image that the twin layer of the formed silver nano-twinned thin film has only 42.8% of (111) crystal orientation, and the proportion of CSL-E3 twin boundary is only 19.6%, which is significantly lower than that of the embodiment with ion-beam bombardment assisted evaporation.

In summary, the present disclosure discloses an novel back side metallization film structure, which is different from the back side metallization film structure of Ti/Ni/poly Ag in the prior art. The novel back side metallization film structure can be directly bonded at a low temperature below 250° C., which is lower than soldering and silver sintering in the prior art. Also, without using the solder or silver sintering paste in the prior art, the Ni diffusion barrier layer of back side metallization in the prior art is not required, so there is no Ni/Ag interface separation and damage problems that often occur in conventional back side metallization layer structures.

In addition, by the method of the present disclosure, a high-density nano-twinned thin film structure with large area can be formed. For example, a complete metallic nano-twinned thin film can be formed on a 6-inch wafer, an 8-inch wafer or a 12-inch wafer, that is, the formed metallic nano-twinned thin film covers the entirety of the surface of the wafer. In contrast, previous methods can only form the high-density twinned thin film structures with small area on the wafers or substrates after dicing. Therefore, the present disclosure also has the advantages of low cost and high production efficiency.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A back side metallization thin film structure, comprising:
a wafer, wherein a plurality of integrated circuit devices are formed on a front side of the wafer; and
a metallic nano-twinned thin film on a back side of the wafer,
wherein the metallic nano-twinned thin film comprises silver, copper, gold, palladium, or nickel,
wherein the metallic nano-twinned thin film comprises a transition layer near the wafer and a twin layer away from the wafer, the twin layer accounts for at least 70% of a thickness of the metallic nano-twinned thin film and comprises parallel-arranged twin boundaries, an average distance between the parallel-arranged twin boundaries is 1 nm to 100 nm, and the parallel-arranged twin boundaries comprise no less than 50% of (111) crystal orientation.

2. The structure as claimed in claim 1, further comprising an adhesive layer disposed between the wafer and the metallic nano-twinned thin film.

3. The structure as claimed in claim 2, wherein a thickness of the adhesive layer is between 0.01 μm and 1 μm.

4. The structure as claimed in claim 2, wherein the adhesive layer comprises titanium, chromium, aluminum, or a combination thereof.

5. The structure as claimed in claim 1, wherein the metallic nano-twinned thin film comprises nano-twinned pillars, wherein a diameter of the nano-twinned pillars is between 0.01 μm and 10 μm.

6. The structure as claimed in claim 1, wherein a thickness of the metallic nano-twinned thin film is between 0.01 μm and 10 μm.

7. The structure as claimed in claim 1, wherein the wafer comprises a single crystal of silicon, silicon carbide, gallium arsenide, or sapphire.

8. The structure as claimed in claim 1, wherein the metallic nano-twinned thin film substantially covers an entirety of the back side of the wafer.

9. The structure as claimed in claim 1, wherein the wafer is a 6-inch wafer, an 8-inch wafer, or a 12-inch wafer.

10. The structure as claimed in claim 1, wherein the metallic nano-twinned thin film covers more than 90% of the surface area of the back side of the wafer.

11. The structure as claimed in claim 1, further comprising a substrate bonded to the back side of the wafer through the metallic nano-twinned thin film.

12. The structure as claimed in claim 1, wherein the integrated circuit devices are power devices.

13. A method of forming a back side metallization thin film structure, comprising:
providing a wafer, wherein a plurality of integrated circuit devices are disposed on a front side of the wafer;
activating a back side of the wafer using ion beam bombardment; and
forming a metallic nano-twinned thin film on the activated back side of the wafer by ion-beam bombardment-assisted evaporation,
wherein the metallic nano-twinned thin film comprises silver, copper, gold, palladium, or nickel,
wherein the metallic nano-twinned thin film comprises a transition layer near the wafer and a twin layer away from the wafer, the twin layer accounts for at least 70% of a thickness of the metallic nano-twinned thin film and comprises parallel-arranged twin boundaries, an average distance between the parallel-arranged twin boundaries is 1 nm to 100 nm, and the parallel-arranged twin boundaries comprise no less than 50% of (111) crystal orientation.

14. The method as claimed in claim 13, further comprising: forming an adhesive layer on the back side of the wafer, and the metallic nano-twinned thin film is formed on a surface of the adhesive layer away from the wafer.

15. The method as claimed in claim 14, wherein the adhesive layer is formed by sputtering or evaporation.

16. The method as claimed in claim 13, wherein the ion-beam bombardment in the activating the back side of the wafer comprises a power of 20 W to 100 W and a duration of 10 minutes to 60 minutes.

17. The method as claimed in claim 13, wherein the ion-beam bombardment in the forming the metallic nano-twinned thin film comprises an ion beam flow rate of 1 sccm to 20 sccm, a voltage of 10V to 5 KV, and a current of 0.2 A to 20 A.

18. The method as claimed in claim 13, further comprising bonding a substrate to the back side of the wafer through the metallic nano-twinned thin film.

19. The method as claimed in claim 13, wherein the wafer comprises a single crystal of silicon, silicon carbide, gallium arsenide, or sapphire.
